(19) United States
(12) Patent Application Publication
(10) Pub. No.: US 2008/0070413 A1
(43) Pub. Date: Mar. 20, 2008

(54) FABRICATION METHODS OF A PATTERNED SAPPHIRE SUBSTRATE AND A LIGHT-EMITTING DIODE

(75) Inventors: Jyh-Chen Chen, Taoyuan (TW); Li-Yun Wu, Yunlin County (TW); Che-Ming Liu, Taipei City (TW); Yeeu-Chang Lee, Miaoli County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: NATIONAL CENTRAL UNIVERSITY, Taoyuan (TW)

(21) Appl. No.: 11/608,250

(22) Filed: Dec. 8, 2006

(30) Foreign Application Priority Data
Sep. 18, 2006 (TW) 95134409

(51) Int. Cl. H01L 21/311

(52) U.S. Cl. 438/700

(57) ABSTRACT

A fabricating method for patterned sapphire substrate is provided. The fabricating method includes the following processes. First, a sapphire substrate is provided, and a mask layer is formed on the sapphire substrate, wherein the mask layer with appropriate pattern exposes a part of the sapphire substrate. Then, a wet etching process is performed to remove the exposed part of the sapphire substrate, wherein an etchant in the wet etching process includes sulfuric acid and the mixture of the sulfuric acid and the phosphoric acid. Next, the mask layer is removed to form the patterned sapphire substrate. Further, a fabricating method for light-emitting diode is provided.

### CROSS-REFERENCE TO RELATED APPLICATION

This application claims the priority benefit of Taiwan application serial no. 95134409, filed on Sep. 18, 2006. All disclosure of the Taiwan application is incorporated herein by reference.

### BACKGROUND OF THE INVENTION

1. Field of the Invention

The present invention relates to a fabricating method for a light-emitting device, and more particularly, to a fabricating method for a patterned sapphire substrate to grow GaN layers.

2. Description of Related Art

The light-emitting diode (LED) has been mainly used in various traffic lights, the electronic products installed in cars, the backlight module of the liquid crystal display, and the general illumination devices. The conventional materials for fabricating an LED capable of emitting visible light include a group of III-V compounds consisting of the AlGaInP and GaN. The AlGaInP is used in the LED emitting red, orange and yellow light; the GaN is used in the LED emitting green, blue and ultraviolet light. The GaN crystal is formed on the sapphire (Al₂O₃) substrate. However, the mismatch between the lattice of the sapphire and the lattice of the GaN crystal results in the high density of threading dislocations of the GaN crystal in the light-emitting diode. The threading dislocations reduce the power of light and lifetime and also increase the current leakage.

Ashby et al. employed an pre-patterned sapphire substrate to grow GaN and AlGaN to reduce threading dislocation. The pre-patterned sapphire substrate is prepared by a photolithography process and an dry etching process to form parallel trenched patterns. The sapphire substrate with trenched patterns and later with other geometric shape are generally called the patterned sapphire substrate (PPS). Then, a plurality of semiconductor layers are sequentially formed on the sapphire substrate to from the LED emitting green or blue or ultraviolet light. This method can efficiently decrease the density of threading dislocations in the GaN crystal and meanwhile due to multiple optical reflection from the side edge of the etched sapphire then increase the power of light provided from the LED.

However, because the sapphire has high chemical stability and high hardness, it is difficult performing the general etching process to form the patterns on the sapphire substrate. For example, the dry etching process has more parameters, low etching speed, high cost and also inherently damages and strains to the substrate; while, the laser assisted etching is not suitable for forming complicated patterns. Therefore, people skilled in this art need to find method with good quality, low cost and high etching speed to fabricate the patterned sapphire substrate.

### SUMMARY OF THE INVENTION

The present invention is directed to a fabricating method for a patterned sapphire substrate to simplify the foresaid etching process, decrease the cost of the etching process, and increase the speed of the etching process.

The present invention is further directed to a fabricating method for an LED to increase the power of outputting light and the external quantum efficiency of the LED.

In order to achieve the above or other advantages, the present invention provides a fabricating method for a patterned sapphire substrate. This method is to provide a sapphire substrate first, and then a mask layer is formed on the sapphire substrate. The mask layer exposes a part of the sapphire substrate. Then, a first wet etching process is performed to remove the exposed part of the sapphire substrate, wherein the etchant in the first etching process includes sulfuric acid. Then, the mask layer is removed.

In one embodiment of the present invention, the etchant in the foresaid first wet etching process further includes phosphoric acid. Besides, in the etchant in the first wet etching process, the composition ratio of the sulfuric acid is larger than that of the phosphoric acid. Moreover, when performing the first wet etching process, the temperature of the etchant in the first wet etching process is between 200° C. and 350° C.

In one embodiment of the present invention, a material of the mask layer is silicon oxide. Besides, the foresaid method to remove the mask layer is performing a second wet etching process, wherein an etchant in the second wet etching process comprises hydrofluoric acid.

In one embodiment of the present invention, the foresaid method for forming the mask layer is to form a mask material layer on the sapphire substrate first and then to form a patterned photoresist layer, wherein the photoresist pattern exposes a part of the mask material layer. Then, the exposed part of the mask material layer and the photoresist pattern are sequentially removed.

In one embodiment of the present invention, the foresaid method for forming the mask layer is to form a layer of photoresist pattern on the sapphire substrate first, wherein the photoresist pattern exposes a part of the sapphire substrate. Next, a mask material layer is formed on the photoresist pattern. Then, the photoresist and a part of the mask material layer thereon are removed by lift-off technique.

In order to achieve the above or other objects, the present invention provides a fabricating method for an LED. This method is to provide a sapphire substrate first, and then a mask layer is formed on the sapphire substrate, wherein the mask layer comprises at least one opening, and the opening exposes a part of the sapphire substrate. Then, a first wet etching process is performed to remove the exposed part of the sapphire substrate, wherein an etchant in the first etching process includes sulfuric acid. Next, the mask layer is removed, and a n-type semiconductor layer, a light emitting layer, and a n-type semiconductor layer are sequentially formed on the sapphire substrate.

In one embodiment of the present invention, the pattern of the opening includes streak, circular or polygonal shapes.

In one embodiment of the present invention, the mask layer has a plurality of the openings, and the patterns of the openings include parallel trenches or cross trenches.

The present invention can simplify the process for fabricating the patterned sapphire substrate, especially reduce the cost of etching process and increase the etching speed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A through FIG. 1E are flow charts showing the steps of a fabricating method for a patterned sapphire substrate of one embodiment of the present invention.

FIG. 1F is a flow chart showing the step of forming an LED on the patterned sapphire substrate in FIG. 1E.

FIG. 2 through FIG. 5 are top views illustrating the sapphire substrate and mask layer. FIG. 1C is the schematic cross-sectional view along the lines I-I, II-II, III-III, and IV-IV of FIG. 2, FIG. 3, FIG. 4 and FIG. 5.

### DESCRIPTION OF EMBODIMENTS

In order to simplify an etching process for a sapphire substrate, reduce the cost of the etching process, and increase the etching speed, the present invention provides a method using a wet etching process to fabricate a patterned sapphire substrate. In the following specification, the foresaid wet etching process is named “the first wet etching process” to distinguish from other wet etching processes. The pure sulfuric acid or the mixture containing sulfuric acid and phosphoric acid is used as an etchant in the first wet etching process. The mechanism of using sulfuric acid (H₂SO₄) and phosphoric acid (H₃PO₄) as the etchant to etch the sapphire substrate (Al₂O₃) is shown respectively as the following formula (1) and (2).

Al₂O₃+3H₂SO₄→Al₂(SO₄)₃+3H₂O (1)

Al₂O₃+2H₃PO₄→2AlPO₄+3H₂O (2)

In this embodiment, if the etchant is the mixture of sulfuric acid and phosphoric acid, rather than the pure sulfuric acid, it is preferable that the composition ratio of sulfuric acid is larger than that of phosphoric acid. Besides, before performing the first etching process, the temperature of the etchant should be as high as 200° C. to 350° C. However, the composition ratio and the temperature of the etchant mentioned here is the preferable example, which can not be used to limit the scope of the present invention. More specifically, since the etching selectivity of the first etching process is decided mainly by the temperature of etchant and the composition ratio of phosphoric acid in the etchant, the temperature of etchant and the composition ratio of phosphoric acid and sulfuric acid can be adjusted according to requirements. Therefore, the foresaid fabricating conditions can not limit the scope of the present invention.

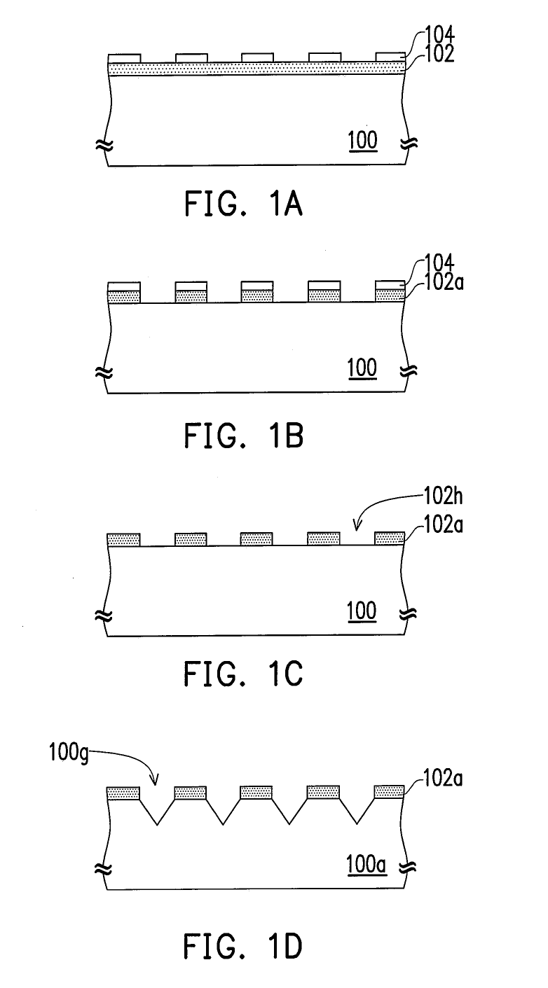

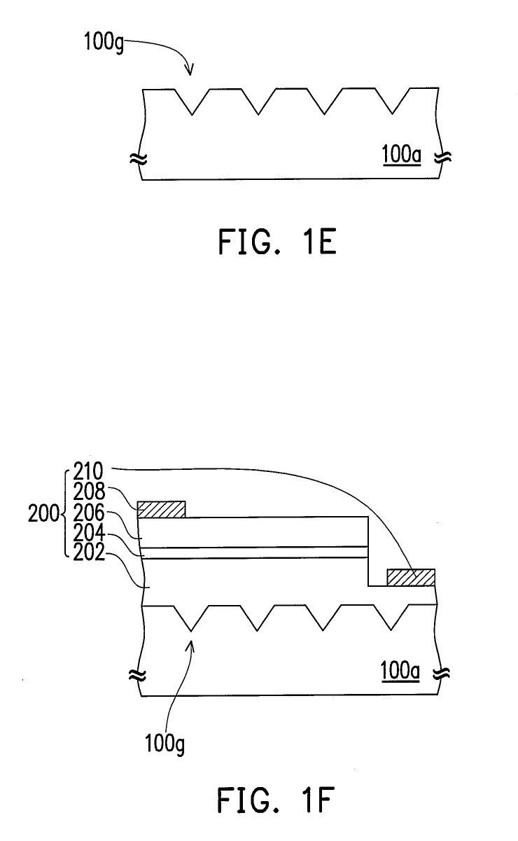

FIG. 1A to FIG. 1F are used to clearly introduce the steps for fabricating the LED in the present invention. FIG. 1A to FIG. 1E are flow charts illustrating the steps for a fabricating method for a patterned sapphire substrate of one embodiment of the present invention. FIG. 1F is a flow chart illustrating the formation of an LED on the patterned sapphire substrate in FIG. 1E.

Please refer to FIG. 1A. First, the sapphire substrate 100 is provided. Then, a mask material layer 102 is formed on the sapphire substrate 100. The method to form the mask material layer 102 is chemical vapor deposition (CVD) or physical vapot deposition (PVD) methods. The material of the mask material layer 102 is the film material, such as silicon oxide, which can prevent the film material from being damaged by high-temperature mixture of sulfuric acid and phosphoric acid. Then, a photoresist pattern 104 is formed on the mask material layer 102, wherein the photoresist pattern 104 exposes a part of the mask material layer 102. The method for forming the photoresist pattern 104 is performing a photolithography process.

Next, please refer to 1B. The exposed part of the mask material layer 102 is removed by using the photoresist pattern 104 as mask. The method to remove the exposed part of the mask material layer 102 is peforming a dry or wet etching process. Thereafter, referring to FIG. 1C, the photoresist pattern 104 is removed. The method to remove the photoresist pattern 104 is performing a wet photoresist-striping process, wherein the solvent of the wet photoresist-striping process includes acetone. Therefore, a mask layer 102a is formed on the sapphire substrate 100, wherein the mask layer 102a is used as the mask for subsequent process of etching the sapphire.

However, the method for forming the mask layer 102 is not limited to the scope of the foresaid method. More specifically, in another embodiment, the method for forming the mask layer 102a is to form a photoresist pattern on the sapphire substrate 100 first, wherein the photoresist pattern exposes a part of the sapphire substrate 100. Next, a mask material layer is formed on the photoresist pattern and the exposed part of the sapphire substrate 100. Then, the photoresist pattern and a portion of the mask material layer thereon are removed by lift-off technique. Through the above-mentioned steps, the mask layer 102a is formed.

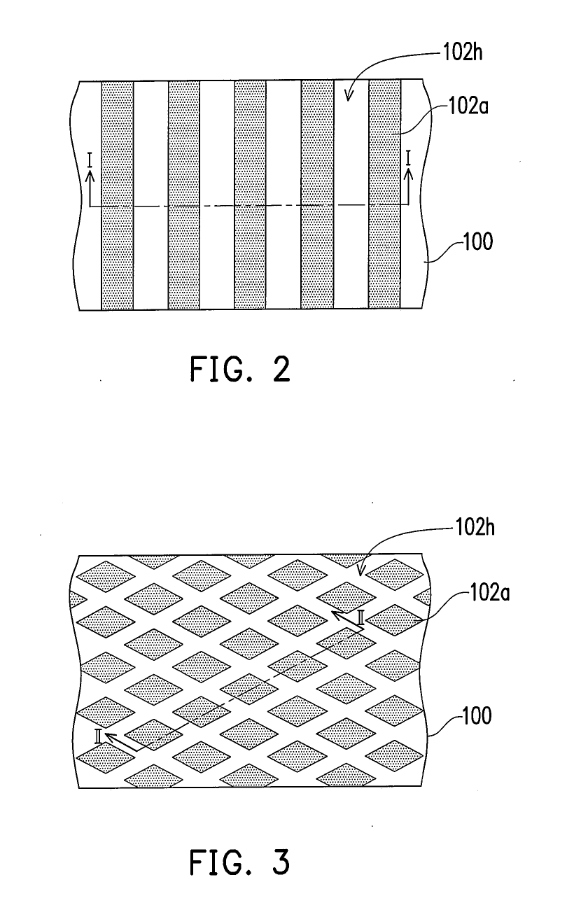

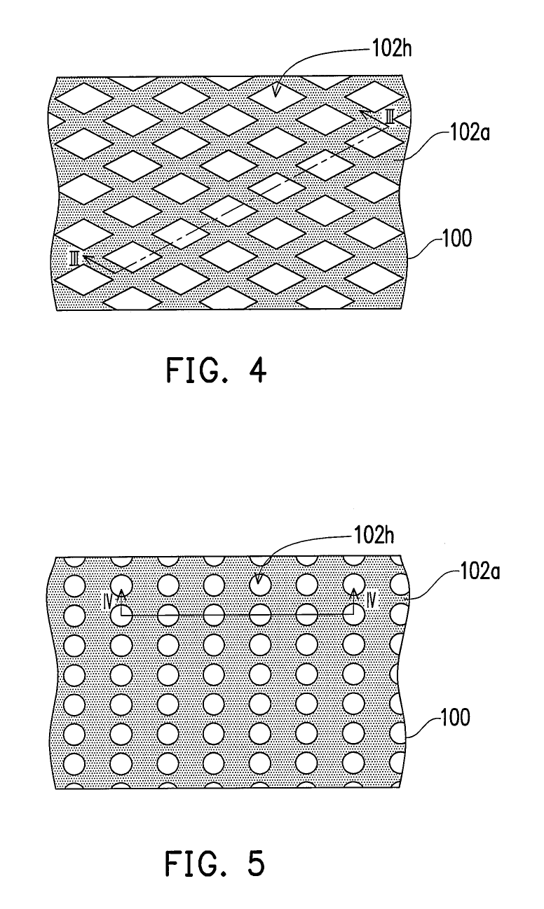

FIG. 2 through FIG. 5 are top views illustrating the sapphire substrate and mask layer. FIG. 1C is the schematic cross-sectional view along the lines I-I, II-II, III-III, and IV-IV of FIG. 2, FIG. 3, FIG. 4 and FIG. 5. Referring to FIG. 2 through FIG. 5, the following descriptions specifically explain the preferable pattern of the mask layer.

Please refer to FIG. 2. The mask layer 102a comprises at least an opening 102h. The openings 102h expose a part of the sapphire substrate 100. The openings 102h may be parallel trenches (as shown in FIG. 2), crossed trenches (as shown in FIG. 3), polygonal shapes (as shown in FIG. 4) or circular shapes (as shown in FIG. 5). The openings 102h in FIG. 2 to FIG. 5 are the commonly known patterns. However, the present invention is not limited to the foresaid scope of patterns. In other words, the patterns of the openings 102h may be adjusted appropriately. For example, the openings 102h may be triangles, streaks of concentric circles, or even non-regular enclosed curves. It should be noted that in the sequent process, the patterns of the openings 102h will be transferred to the sapphire substrate 100 so as to form the patterned sapphire substrate. The patterned sapphire substrate is used to fabricate the LED. The patterns of the openings 102h determine the quality and the external quantum efficiency of the LED. This will be explained in the following description.

Next, please refer to FIG. 1D. After the mask layer 102a is formed, the foresaid first wet etching process is performed to remove the exposed part of the sapphire substrate 100 so as to form the patterned sapphire substrate 100a. In the present embodiment, after the performance of the first wet etching process, trenches 100g are formed on the surface of the patterned sapphire substrate 100a. The sections of the trenches 100g are asymmetric patterns or the symmetric patterns like U shape or V shape. However, since the sections of the trenches 100g are determined by the crystal orientation of the sapphire substrate 100, the sections of the trenches 100g are not limited to the V shape. It is obvious that in the top views of the patterned sapphire substrate 100a, the patterns and the dispositions of the trenches 100g are the same with the ones of the openings 102h.

Then, referring to FIG. 1E, the mask layer 102a is removed. The method of removing the mask layer 102a includes performing a second wet etching process, for example. An etchant in the second wet etching process is the acid capable of removing the mask layer 102a. For example, when the material of the mask layer 102a is silicon oxide, the hydrofluoric acid is used as the etchant. Those who are skilled in the art know that the etchant includes the diluted hydrofluoric acid. So far, the process for fabricating the patterned sapphire substrate has been finished.

Then, please refer to FIG. 1F. The LED 200 is formed on the patterned sapphire substrate 100a. The LED 200 at least consists of a n-type semiconductor layer 202, a light emitting layer 204, and a p-type semiconductor layer 206. The n-type semiconductor layer 202, the light emitting layer 204 and the p-type semiconductor layer 206 are sequentially stacked on the patterned sapphire substrate 100a.

It should be noted that the LED 200 is formed on the patterned sapphire substrate 100a. The patterned sapphire substrate 100a contains the trenches 100g. Compared with the LED of prior art, the fabricating method of the present invention can efficiently reduce the density of threading dislocations in the n-type semiconductor layer 202. Furthermore, the designers can adjust the patterns of the openings 102h and the dispositions thereof to increase the external quantum efficiency of the LED 200. More specifically, the suitable patterns of the openings and the periodical disposition of the openings 102h can result in the extra reflections of the green, blue or ultraviolet light emitted from the LED 200 between the sapphire and n-type semiconductor layer 202. Therefore, the power of outputting light of the LED 200 can be further increased.

In summary, the fabricating method for the patterned sapphire substrate of the present invention has at least the following advantages:

1. Compared with the dry etching process, since the parameters of the first wet etching process are fewer, the fabricating method of the present invention can simplify the steps for etching the sapphire substrate. The present wet etching method also avoid the damages and strains generated by dry etching. Besides, since the present invention does not use the expensive dry etching machine, the cost of the etching process can be reduced.

2. The etching rate of the first wet etching process is as fast as 1 micrometers per minute.

3. The first wet etching process can be used to form the large area and uniform regular patterns on the sapphire substrates.

4. The first wet etching process can use the like process conditions to etch large quantity of sapphire substrates (wafers). Therefore, through the first wet etching process, the patterned sapphire substrates can be massively produced and possess a uniform quality. Since the dry etching process is limited to the space of the vacuum chamber and the process operation time, the capacity is lower than the first wet etching process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabricating method for a patterned sapphire substrate, comprising:
providing a sapphire substrate;
forming a mask layer on the sapphire substrate, wherein the mask layer exposes a part of the sapphire substrate;
performing a first wet etching process to remove the exposed part of the sapphire substrate, wherein an etchant in the first wet etching process includes sulfuric acid; and
removing the mask layer.

2. The fabricating method as claimed in claim 1, wherein the etchant in the first wet etching process further includes phosphoric acid.

3. The fabricating method as claimed in claim 2, wherein in the etchant in the first wet etching process, the composition ratio of the sulfuric acid is larger than that of the phosphoric acid.

4. The fabricating method as claimed in claim 3, wherein when performing the first wet etching process, the temperature of the etchant in the first wet etching process is between 200° C. and 350° C.

5. The fabricating method as claimed in claim 1, wherein a material constituting the mask layer is silicon oxide.

6. The fabricating method as claimed in claim 5, wherein the method to remove the mask layer is performing a second wet etching process, and an etchant in the second wet etching process includes hydrofluoric acid.

7. The fabricating method as claimed in claim 5, wherein the method for forming the mask layer comprises:
forming a mask material layer on the sapphire substrate;
forming a photoresist pattern on the mask material layer, wherein the photoresist pattern exposes a part of the mask material layer;
removing the exposed part of the mask material layer; and
removing the photoresist pattern.

8. The fabricating method as claimed in claim 5, wherein the method for forming the mask layer comprises:
forming a photoresist pattern on the sapphire substrate, wherein the photoresist pattern exposes a part of the sapphire substrate;
forming a mask material layer on the photoresist pattern and on the exposed part of the sapphire substrate; and
removing the photoresist pattern and a part of the mask material layer thereon by lift-off technique.

9. A fabricating method for a light-emitting diode, comprising:
providing a sapphire substrate;
forming a mask layer on the sapphire substrate, wherein the mask layer has at least one opening to expose a part of the sapphire substrate;
performing a first wet etching process to remove the exposed part of the sapphire substrate, wherein an etchant in the first wet etching process includes sulfuric acid;
removing the mask layer; and
sequentially forming a n-type semiconductor layer, a light-emitting layer, and a p-type semiconductor layer on the sapphire substrate.

10. The fabricating method as claimed in claim 9, wherein the etchant in the first wet etching process further includes phosphoric acid.

11. The fabricating method as claimed in claim 10, wherein in the etchant in the first wet etching process, the composition ratio of the sulfuric acid is larger than that of the phosphoric acid.

12. The fabricating method as claimed in claim 11, wherein when performing the first wet etching process, the temperature of the etchant in the first wet etching process is between 200° C. and 350° C.

13. The fabricating method as claimed in claim 9, wherein a material constituting the mask layer is silicon oxide.

14. The fabricating method as claimed in claim 13, wherein the method for removing the mask layer is performing a second wet etching process, and an etchant in the second wet etching process includes hydrofluoric acid.

15. The fabricating method as claimed in claim 13, wherein the method for forming the mask layer comprises:
forming a mask material layer on the sapphire substrate;
forming a photoresist pattern on the mask material layer, wherein the photoresist pattern exposes a part of the mask material layer;
removing the exposed part of the mask material layer; and
removing the photoresist pattern.

16. The fabricating method as claimed in claim 13, wherein the method for forming the mask layer comprises:
forming a photoresist pattern on the sapphire substrate, wherein the photoresist pattern exposes a part of the sapphire substrate;
forming a mask material layer on the photoresist pattern and on the exposed part of the sapphire substrate; and
removing the photoresist pattern and a part of the mask material layer thereon by lift-off technique.

17. The fabricating method as claimed in claim 9, wherein the pattern of the opening includes streak, circular or polygonal shape.

18. The fabricating method as claimed in claim 9, wherein the mask layer has a plurality of the openings, and the patterns of the openings include parallel trenches or cross trenches.
